(19) United States
(12) Patent Application Publication
(10) Pub. No.: US 2015/0035128 A1
(43) Pub. Date: Feb. 5, 2015

(54) SEMICONDUCTOR DEVICE AND METHOD OF MANUFACTURING SEMICONDUCTOR DEVICE

(71) Applicant: Kabushiki Kaisha Toshiba, Minato-ku (JP)

(72) Inventor: Hiroyuki MAEDA, Kawasaki-shi (JP)

(73) Assignee: Kabushiki Kaisha Toshiba, Minato-ku (JP)

(21) Appl. No.: 14/151,260

(22) Filed: Jan. 9, 2014

Related U.S. Application Data
(60) Provisional application No. 61/861,461, filed on Aug. 2, 2013.

(51) Int. Cl. H01L 23/00; H01L 21/48

(52) U.S. Cl. CPC H01L 23/562; H01L 21/4842
USPC 257/666; 438/123

(57) ABSTRACT

According to one embodiment, a semiconductor device includes a metal holder, a semiconductor chip on the holder, and a reinforcing portion. The reinforcing portion is formed by bending a portion of the holder, the reinforcing portion includes a groove depressed from a surface of the holder and a protrusion on a back of the groove.

### CROSS-REFERENCE TO RELATED APPLICATIONS

This application claims the benefit of U.S. Provisional Application No. 61/861,461, filed Aug. 2, 2013, the entire contents of which are incorporated herein by reference.

### FIELD

Embodiments described herein relate generally to semiconductor devices and methods of manufacturing the semiconductor devices.

### BACKGROUND

A semiconductor device having a semiconductor chip sealed with mold resin is provided.

It is desired to prevent the semiconductor chip of the semiconductor device from being damaged.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a cross-sectional view schematically showing a semiconductor device according to a first embodiment.

FIG. 2 is a plan view schematically showing a holder of the semiconductor device of FIG. 1.

FIG. 3 is a plan view schematically showing the internal configuration of the semiconductor device of FIG. 1.

FIG. 4 is a flowchart showing one example of a manufacturing method of the semiconductor device of FIG. 1.

FIG. 5 is a plan view schematically showing a holder of a semiconductor device according to a second embodiment.

FIG. 6 is a plan view schematically showing the internal configuration of the semiconductor device of FIG. 5.

FIG. 7 is a cross-sectional view schematically showing a semiconductor device according to a third embodiment.

FIG. 8 is a plan view schematically showing the internal configuration of the semiconductor device of FIG. 7.

FIG. 9 is a cross-sectional view schematically showing a first modification of a reinforcing portion.

FIG. 10 is a cross-sectional view schematically showing a second modification of the reinforcing portion.

FIG. 11 is a plan view schematically showing the internal configuration of a semiconductor device according to a fourth embodiment.

FIG. 12 is a plan view schematically showing the internal configuration of a semiconductor device according to a fifth embodiment.

FIG. 13 is a plan view schematically showing the internal configuration of a semiconductor device according to a sixth embodiment.

FIG. 14 is a plan view schematically showing the internal configuration of a semiconductor device according to a seventh embodiment.

FIG. 15 is a plan view schematically showing the internal configuration of a semiconductor device according to an eighth embodiment.

### DETAILED DESCRIPTION

Various embodiments will be described hereinafter with reference to the accompanying drawings.

In general, according to one embodiment, a semiconductor device comprises a metal holder, a semiconductor chip mounted on the holder, and a reinforcing portion. The reinforcing portion is formed by bending a portion of the holder, the reinforcing portion comprising a groove depressed from a surface of the holder and a protrusion on a back of the groove.

In this specification, some components are expressed by two or more terms. Those terms are just examples. Those components may be further expressed by another or other terms. And the other components which are not expressed by two or more terms may be expressed by another or other terms.

The drawings are schematically illustrated. In the drawings, in some cases, the relationship between a thickness and planar dimensions or the scale of the thickness of each layer may be different from the actual relationship or scale. In addition, in the drawings, components may have different dimensions or scales.

### First Embodiment

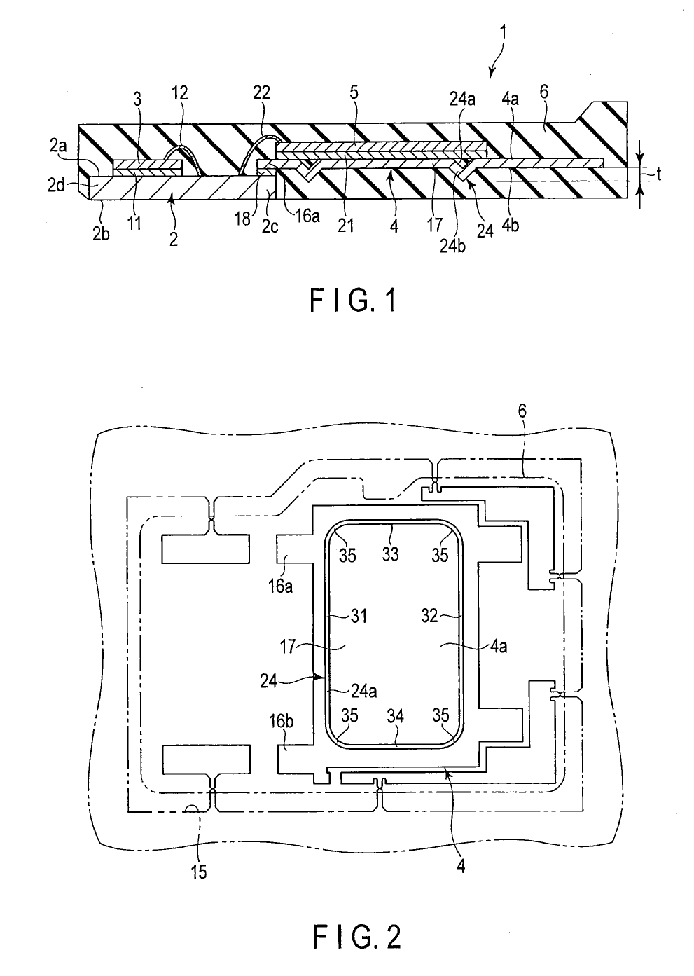

FIG. 1 to FIG. 4 show a semiconductor device 1 according to a first embodiment. For example, the semiconductor device 1 is a semiconductor memory device and is, for example, a NAND flash memory. One example of the semiconductor device 1 is a micro SD (trademark) card, but is not limited to this.

FIG. 1 is a cross-sectional view schematically showing the semiconductor device 1. As shown in FIG. 1, the semiconductor device 1 is a so-called SiP (system in a package) type semiconductor device and includes a board 2, controller chip 3, holder 4, semiconductor chip 5 and sealing portion 6.

The board 2 (e.g., wiring board) includes a glass epoxy resin base member and a wiring pattern formed on the base member. The board 2 has a first surface 2a (e.g., mounting surface) and a second surface 2b (e.g., external terminal surface) positioned on the opposite side of the first surface 2a. The first surface 2a and second surface 2b are set substantially parallel to each other and are formed to extend in an extending direction of the board 2.

A wiring pattern is formed on the first surface 2a of the board 2. For example, external connection terminals exposed to the exterior of the semiconductor device 1 are provided on the second surface 2b of the board 2. Further, the board 2 includes a first end portion 2c and a second end portion 2d positioned on the opposite side of the first end portion 2c.

As shown in FIG. 1, the controller chip 3 is mounted on the first surface 2a of the board 2. The controller 3 is one example of each of a “component”, “electronic component” and “first semiconductor chip”. The controller chip 3 controls the operation of the semiconductor chip 5. For example, the controller chip 3 performs data write, read and erase operations in response to a command from the exterior and manages the data storage state of the semiconductor chip 5.

An adhesive film 11 (i.e., adhesive layer) is provided between the controller chip 3 and the first surface 2a of the board 2. The controller chip 3 is fixed on the first surface 2a of the board 2 via the adhesive film 11. Further, the controller chip 3 is electrically connected to the first surface 2a of the board 2 via a bonding wire 12.

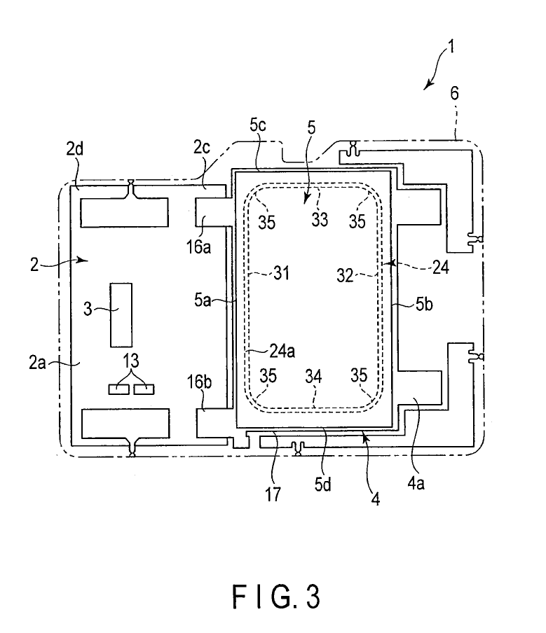

A passive component 13 is mounted on the first surface 2a of the board 2 (see FIG. 3). The passive component 13 is one example of a “component” and “electronic component”. For example, the passive component 13 is a capacitor or resistor, but is not limited to this. The passive component 13 is electrically connected to the board 2.

FIG. 2 is a plan view schematically showing the holder 4 of the semiconductor device 1. FIG. 3 is a plan view schematically showing the internal configuration of the semiconductor device 1. The holder 4 (e.g., supporting portion, mounting portion, table, frame, or lead frame, base) is attached to the first end portion 2c of the board 2 and extends to a great extent in an exterior of the board 2. The holder 4 extends substantially parallel to the board 2.

For example, the holder 4 is larger than the board 2. The holder 4 is formed of a metal plate member and is made thinner than the board 2. The holder 4 is formed by cutting out a portion of the base member 15 (see FIG. 2) that is a metal plate, for example.

For example, the holder 4 includes a pair of first portions 16a, 16b (e.g., attaching portions) and a second portion 17 (e.g., bed portion). The first portions 16a, 16b are attached to the first surface 2a of the board 2. An adhesive film 18 (i.e., adhesive layer) is provided between the first portions 16a, 16b and the board 2. The first portions 16a, 16b are fixed on the first surface 2a of the board 2 via the adhesive film 18. As shown in FIG. 2, the pair of first portions 16a, 16b are separately arranged on both ends of the holder 4 in the width direction.

As shown in FIG. 1 and FIG. 3, the second portion 17 of the holder 4 is a portion on which the chip is mounted. The second portion 17 extends from the first portions 16a, 16b to the outside of the board 2. The second portion 17 is positioned outside the board 2. That is, the second portion 17 is a portion protruding (i.e., projecting, or overhung) from the board 2 and is not overlapped with the board 2 in the thickness direction of the semiconductor device 1 (i.e., the thickness direction of the board 2).

As shown in FIG. 1 and FIG. 3, the semiconductor chip 5 (i.e., the second semiconductor chip) is mounted on the second portion 17 of the holder 4 from the opposite side of the board 2. For example, the semiconductor chip 5 is a desired memory chip and is, for example, a NAND flash memory chip.

More specifically, the holder 4 has a first surface 4a on which the semiconductor chip 5 is mounted and a second surface 4b positioned on the opposite side of the first surface 4a. The second surface 4b faces the board 2 and is attached to the board 2.

As shown in FIG. 1, an adhesive film 21 (i.e., adhesive layer) is provided between the semiconductor chip 5 and the holder 4. The semiconductor chip 5 is fixed on the holder 4 via the adhesive film 21. A bonding wire 22 is provided between the semiconductor chip 5 and the board 2. The semiconductor chip 5 is electrically connected to the first surface 2a of the board 2 via the bonding wire 22.

As shown in FIG. 1 to FIG. 3, a reinforcing portion 24 (e.g., groove processed portion, or press processed portion) is provided on the second portion 17 of the holder 4. The reinforcing portion 24 is formed by bending a portion of the holder 4 by press-processing, for example. The reinforcing portion 24 includes a groove 24a (i.e., recess) depressed from the surface of the holder 4 and a linear protrusion 24b provided on the back of the groove 24a.

The protrusion 24b is a portion that projects to the opposite side of the groove 24a by forming the groove 24a by press-processing. The protrusion 24b is integrally formed with the groove 24a and extends along the groove 24a. In this embodiment, the protrusion 24b is a triangular (e.g., isosceles triangular) bent portion.

In this embodiment, the reinforcing portion 24 is positioned in a portion covered with the semiconductor chip 5 and overlaps with the semiconductor chip 5 in the thickness direction of the holder 4. In this embodiment, the groove 24a is formed in the first surface 4a of the holder 4 and the protrusion 24b is provided on the second surface 4b. That is, the protrusion 24b projects from the opposite side with respect to the semiconductor chip 5. Therefore, the protrusion 24b does not interfere with the semiconductor chip 5. The projection amount t of the protrusion 24b is larger than the thickness of the holder 4, for example.

In one example, in the semiconductor device 1 having the board 2 with the thickness of 230 μm and the holder 4 with the thickness of 127 μm, the projection amount t of the protrusion 24b may be set to a desired height if the projection amount is less than 330 μm that is set within the external form of the semiconductor device 1.

As shown in FIG. 3, the reinforcing portion 24 of this embodiment is formed in a frame form to surround the central portion of the semiconductor chip 5. More specifically, the semiconductor chip 5 has a first side 5a, second side 5b, third side 5c and fourth side 5d that define the external form thereof. The reinforcing portion 24 has a first line 31 extending along the first side 5a, second line 32 extending along the second side 5b, third line 33 extending along the third side 5c, fourth line 34 extending along the fourth side 5d and arc portions 35 connecting the lines.

As shown in FIG. 1 to FIG. 3, the semiconductor device 1 includes the sealing portion 6 (i.e., resin portion, mold, or mold resin portion). One example of the sealing portion 6 is resin (i.e., epoxy resin). The sealing portion 6 integrally covers (i.e., integrally seals) the first surface 2a of the board 2, controller chip 3, holder 4, semiconductor chip 5, reinforcing portion 24 and bonding wires 12, 22. The sealing portion 6 forms the external form of the package of the semiconductor device 1.

Next, one example of the manufacturing method of the semiconductor device 1 is explained.

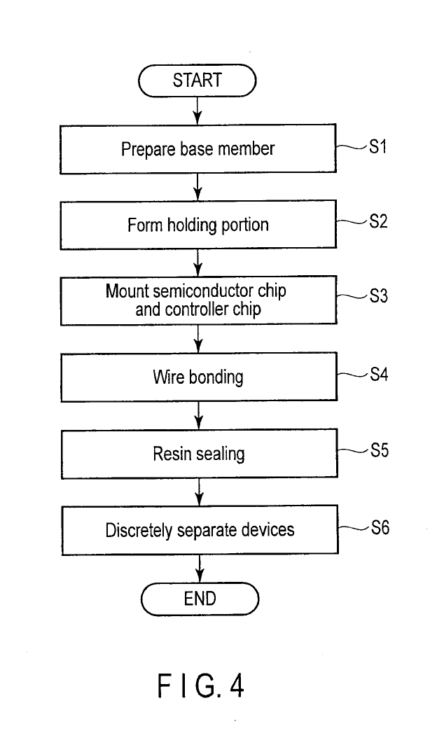

FIG. 4 is a flowchart showing one example of the manufacturing method of the semiconductor device 1. As shown in FIG. 4, first, a base member 15 used as a material of a holder 4 is prepared (step S1). For example, the base member 15 is a metal plate from which a plurality of holders 4 can be cut out.

Next, the holders 4 are formed by press-processing (step S2). At this time, a reinforcing portion 24 is formed on each holder 4 at the same time as the external form of the holder 4 is processed. That is, a shape for processing the reinforcing portion 24 is formed on a press die used for processing an external form of the holder 4. Therefore, the external form of the holder 4 and the reinforcing portion 24 are substantially simultaneously formed by one press-processing.

Then, a semiconductor chip 5 is mounted on the holder 4 and a controller chip 3 is mounted on the board 2 (step S3). The order of the operations for mounting the semiconductor chip 5 and mounting the controller chip 3 can be freely selected.

Next, wire bonding is performed for the semiconductor chip 5 and controller chip 3 to electrically connect the semiconductor chip 5 and controller chip 3 to the board 2 (step S4). After this, mold resin is injected to form a sealing portion 6 that covers the semiconductor chip 5 and controller chip 3 (step S5).

Then, the semiconductor devices 1 are separated from the base member 15 to discretely provide the semiconductor devices 1 (step S6). As a result, the semiconductor device 1 can be obtained.

According to the semiconductor device 1 thus configured, the semiconductor chip 5 can be prevented from being damaged. That is, a defect such as a “crack” or “breakage” may sometimes occur in the semiconductor chip mounted on the product body or on the internal portion thereof when the “load” or “force in the bending direction” is applied to the semiconductor device at the manufacturing time of the semiconductor device or at the use time of the product (e.g., at the insertion or removal time, or storage time). This is because external stress tends to act on the semiconductor chip since the holder on which the semiconductor chip is placed is thin.

Therefore, on the semiconductor device 1 of this embodiment, the reinforcing portion 24 formed by bending a portion of the holder 4 is provided. The reinforcing portion 24 includes a groove 24a depressed from the surface of the holder 4 and a protrusion 24b positioned on the back of the groove 24a. By providing the reinforcing portion 24 on the holder 4, the strength of the holder 4 is increased and becomes difficult to be bent or distorted. Therefore, stress becomes difficult to act on the semiconductor chip 5 placed on the holder 4 and the semiconductor chip 5 can be prevented from being damaged.

The inventors of this application made the following trial calculations and comparisons for validation. As a trial calculation model, forces (cantilever/front-end loading model) required for bending 1 mm a plane-form plate member and a plate member having a reinforcing portion press-processed into an isosceles triangular form while the material of copper is used and the size is set to the length of 50×width of 50×thickness of 1 mm are subjected to the trial calculations and comparisons. As a result, it is determined that force that is almost three times the force required for bending the plane-form plate member by 1 mm is required for bending the plate member having the reinforcing portion by 1 mm (that is, the bending strength is three times). Therefore, it is understood that the strength of the holder 4 can be increased by providing the reinforcing portion 24 on the holder 4.

In this embodiment, the reinforcing portion 24 is provided in a portion covered with the semiconductor chip 5. The protrusion 24b projects toward the opposite side with respect to the semiconductor chip 5. Thus, the reinforcing portion 24 can be provided in the portion covered with the semiconductor chip 5 and the reliability of a region of the holder 4 on which the semiconductor chip 5 is placed can be enhanced. As a result, the semiconductor chip 5 can be further prevented from being damaged.

In this embodiment, the reinforcing portion 24 is formed in a frame form to surround the central portion of the semiconductor chip 5. With the reinforcing portion 24 of the above form, the strength against the stress such as bending and distortion is increased and the semiconductor chip 5 can be further effectively protected. Further, with the reinforcing portion 24 of the above form, the central portion of the semiconductor chip 5 that tends to be easily damaged can be effectively protected.

Next, semiconductor devices 1 according to second to eighth embodiments are explained. The configurations that have the same or similar functions as or to those of the configurations of the first embodiment are denoted by the same symbols and the explanation thereof is omitted. Further, the configurations other than those explained below are the same as those of the first embodiment.

### Second Embodiment

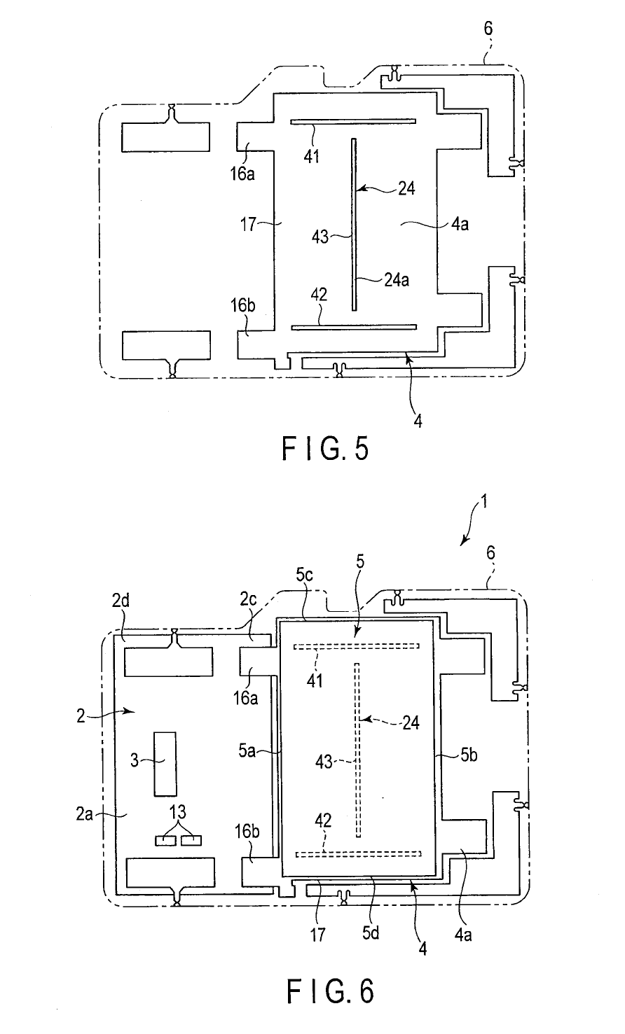

Next, a semiconductor device 1 according to a second embodiment is explained with reference to FIG. 5 and FIG. 6. FIG. 5 is a plan view schematically showing a holder 4 of the semiconductor device 1. FIG. 6 is a plan view schematically showing the internal configuration of the semiconductor device 1.

As shown in FIG. 5 and FIG. 6, a reinforcing portion 24 of this embodiment is not formed in a surrounding form and is partly (i.e., selectively) formed on the holder 4. For example, the reinforcing portion 24 includes three portions, that is, a first line 41, second line 42 and third line 43. The first line 41 extends along a third side 5c of a semiconductor chip 5. The second line 42 extends substantially parallel to the first line 41 and extends along a fourth side 5d of the semiconductor chip 5. The third line 43 extends in a direction that intersects with (e.g., substantially perpendicular to) the first line 41 and second line 42. The third line 43 is positioned on the back of the central portion of the semiconductor chip 5 and extends between the first line 41 and the second line 42.

Like the first embodiment, with the semiconductor device 1 of the above configuration, the semiconductor chip 5 can be prevented from being damaged. In this embodiment, the reinforcing portion 24 includes a portion positioned on the back of the central portion of the semiconductor chip 5. With the reinforcing portion 24 of the above form, the central portion of the semiconductor chip 5 that tends to be damaged can be effectively protected.

### Third Embodiment

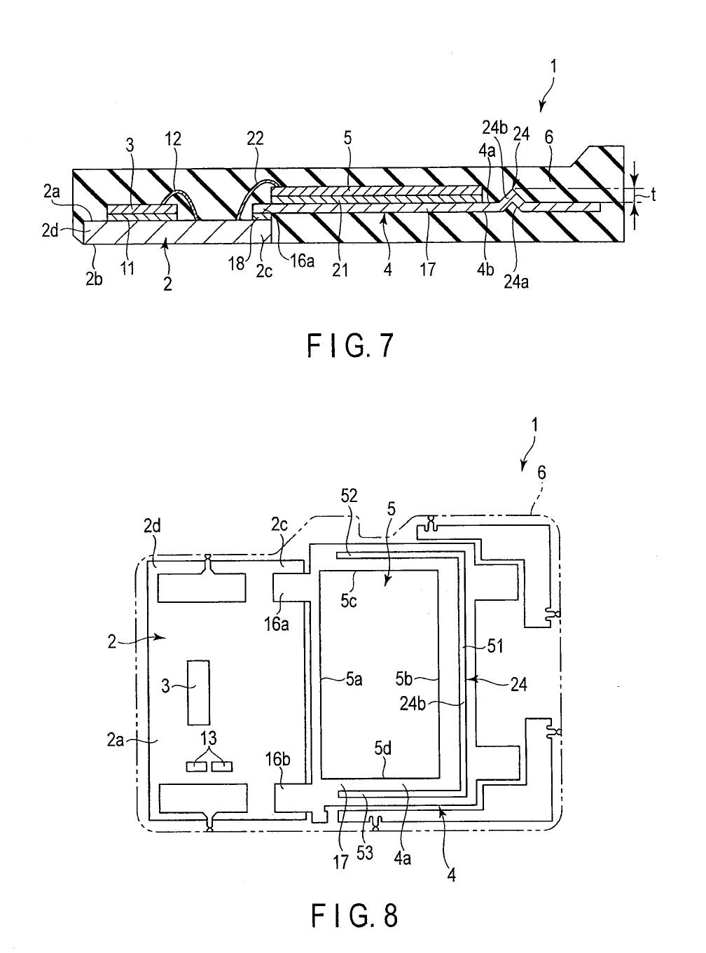

Next, a semiconductor device 1 according to a third embodiment is explained with reference to FIG. 7 and FIG. 8. FIG. 7 is a cross-sectional view schematically showing the semiconductor device 1. FIG. 8 is a plan view schematically showing the internal configuration of the semiconductor device 1.

As shown in FIG. 7, a reinforcing portion 24 of this embodiment projects in a direction opposite to that of the first embodiment. That is, a groove 24a is formed in a second surface 4b of a holder 4 and a protrusion 24b is formed on a first surface 4a. The projection amount t of the protrusion 4 is larger than the thickness of the holder 4, for example.

In one example, in the semiconductor device 1 having a board 2 with the thickness of 230 μm and the holder 4 with the thickness of 127 μm, the projection amount t of the protrusion 24b may be set to a desired height if the projection amount is less than 173 μm that is set within an external form of the semiconductor device 1.

As shown in FIG. 8, the reinforcing portion 24 is provided in a position separated from a semiconductor chip 5 and is not overlapped with the semiconductor chip 5. The reinforcing portion 24 is provided around the semiconductor chip 5 to surround at least a portion of the semiconductor chip 5. The reinforcing portion 24 has a first line 51, second line 52 and third line 53.

The first line 51 extends along a second side 5b of the semiconductor chip 5. The second line 52 extends along a third side 5c of the semiconductor chip 5. The third line 53 extends along a fourth side 5d of the semiconductor chip 5. The first to third lines 51, 52, 53 may be separately provided, but it is preferable because the strength of the holder 4 is increased if the lines are connected to one another.

Like the first embodiment, with the semiconductor device 1 of the above configuration, the semiconductor chip 5 can be prevented from being damaged. In this embodiment, the reinforcing portion 24 is provided in a position separated from the semiconductor chip 5. The protrusion 24b is provided on the first surface 4a of the holder 4. According to the above configuration, the reinforcing portion 24 can be provided on the holder 4 even if the protrusion 24b cannot be provided on the second surface 4b of the holder 4. Further, if the reinforcing portion 24 is provided to surround at least a portion of the semiconductor chip 5, the semiconductor chip 5 can be further effectively protected.

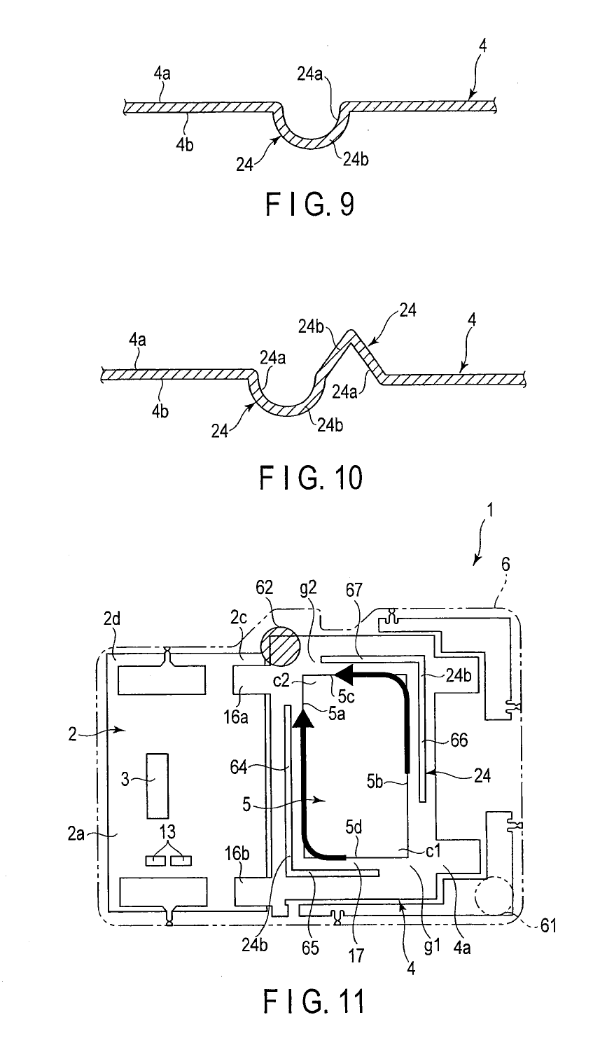

Next, modifications of the reinforcing portion 24 according to the first to third embodiments are explained with reference to FIG. 9 and FIG. 10. As shown in FIG. 9, the reinforcing portion 24 is not limited to the triangular bent portion as in the first to third embodiments and, for example, may be an arc-shaped bent portion. Further, as shown in FIG. 10, the reinforcing portion 24 may be a combined form of a plurality of forms, for example, a triangular bent portion and an arc-shaped bent portion. The cross-section of the reinforcing portion 24 is not particularly limited if the shape of the reinforcing portion can be formed by use of a press technique. These modifications can be applied to all of the following embodiments.

### Fourth Embodiment

Next, a semiconductor device 1 according to a fourth embodiment is explained with reference to FIG. 11. FIG. 11 is a plan view schematically showing a holder 4 of the semiconductor device 1.

As shown in FIG. 11, a sealing portion 6 includes an injection port 61 via which resin (e.g., mold resin) is injected to form the sealing portion 6. The injection port 61 is left behind on the surface of the sealing portion 6 as a trace of an entrance via which resin is injected. The injection port 61 is a region that faces an injection hole of a die used in the resin injection process. In this embodiment, the injection port 61 is formed in a corner portion of the sealing portion 6.

As shown in FIG. 11, the sealing portion 6 has a back portion 62. The back portion 62 is positioned on the opposite side of the injection port 61 in a semiconductor chip 5. The back portion 62 is one example of “a region to sandwich the semiconductor chip in cooperation with the injection port”. Since the back portion 62 is positioned on the diagonally opposite side of the injection 61, for example, the resin flowing distance is long. In this case, since the semiconductor chip 5 acts as an obstacle (i.e., resistance matter) and disturbs filling of resin, it becomes one of the regions that cause the filling property to become worse. For convenience of the explanation, the back portion 62 is hatched.

The semiconductor chip 5 includes a first corner portion c1 and a second corner portion c2. The first corner portion c1 is a corner portion nearest to the injection port 61 among the four corner portions of the semiconductor chip 5. The second corner portion c2 is diagonally positioned with respect to the first corner portion c1. The back portion 62 is arranged adjacent to the second corner portion c2, for example.

As shown in FIG. 11, a reinforcing portion 24 projects from a first surface 4a of the holder 4. The reinforcing portion 24 is provided around the semiconductor chip 5 to surround at least a portion of the semiconductor chip 5. The reinforcing portion 24 has a first line 64, a second line 65, a third line 66 and a fourth line 67.

The first line 64 extends along a first side 5a of the semiconductor chip 5. The second line 65 extends in a direction intersecting with (e.g., substantially perpendicular to) the first line 64 and extends along a fourth side 5d of the semiconductor chip 5. The second line 65 is connected to the first line 64. As a result, an L-shaped first reinforcing portion is formed.

On the other hand, the third line 66 extends along a second side 5b of the semiconductor chip 5. The fourth line 67 extends in a direction intersecting with (e.g., substantially perpendicular to) the third line 66 and extends along a third side 5c of the semiconductor chip 5. The fourth line 67 is connected to the third line 66. As a result, an L-shaped second reinforcing portion is formed.

As shown in FIG. 11, gap g1 is provided between the second line 65 and the third line 66. Further, gap g2 is provided between the first line 64 and the fourth line 67. Therefore, resin injected via the injection port 61 can flow to the back portion 62 via gap g1 between the second line 65 and the third line 66 and gap g2 between the first line 64 and the fourth line 67.

As shown in FIG. 11, the reinforcing portion 24 includes a portion extending toward the back portion 62. In this embodiment, the first line 64 and fourth line 67 extend toward the back portion 62. Therefore, a portion of resin injected via the injection port 61 flows along the first line 64 and fourth line 67 (i.e., guided by means of the first line 64 and fourth line 67) and led toward the back portion 62. That is, with the manufacturing method of the semiconductor device 1 according to this embodiment, resin is caused to flow along the reinforcing portion 24 and the stable amount of resin can be supplied to the back portion 62.

With the above configuration, like the first embodiment, the semiconductor chip 5 can be prevented from being damaged. Further, in this embodiment, the filling property in the sealing portion 6 can be enhanced. That is, in the semiconductor device 1 of this embodiment, the reinforcing portion 24 includes a portion extending toward the back portion 62 of the sealing portion 6.

In this embodiment, the movement of resin can be controlled if the groove or protrusion is provided on the flow passage. Therefore, if the reinforcing portion 24 includes the portion extending toward the back portion 62 of the sealing portion 6 as in this embodiment, a portion of resin injected via the injection port 61 is guided by means of the groove 24a and protrusion 24b of the reinforcing portion 24 and led toward the back portion 62 of the sealing portion 6.

As a result, insufficient filing in the sealing portion 6 can be suppressed. That is, the reinforcing portion 24 has an effect of increasing the strength of the holder 4 and enhancing the filling property of resin.

### Fifth Embodiment

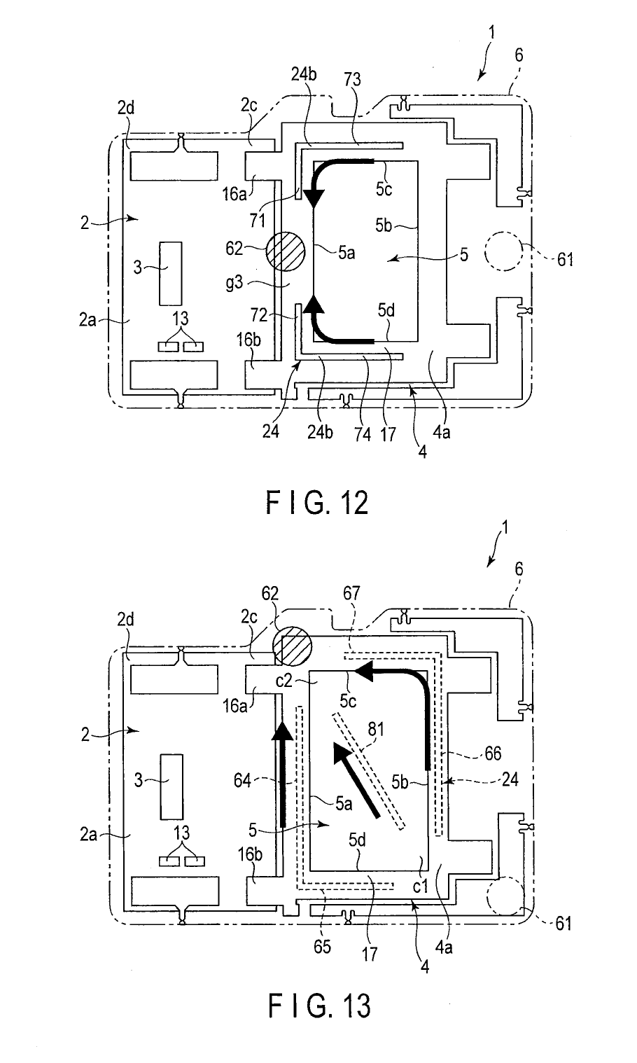

Next, a semiconductor device 1 according to a fifth embodiment is explained with reference to FIG. 12. FIG. 12 is a plan view schematically showing a holder 4 of the semiconductor device 1. The configurations that have the same or similar functions as or to those of the configurations of the fourth embodiment are denoted by the same symbols and the explanation thereof is omitted. Further, the configurations other than those explained below are the same as those of the fourth embodiment.

As shown in FIG. 12, in this embodiment, an injection port 61 is positioned in a central portion of the end portion of a sealing portion 6. A back portion 62 is positioned on the opposite side of the injection port 61 with a semiconductor chip 5 disposed therebetween. A reinforcing portion 24 has a first line 71, a second line 72, a third line 73 and a fourth line 74.

The first line 71 extends along a first side 5a of the semiconductor chip 5. The second line 72 extends along the first side 5a of the semiconductor chip 5 with gap g3 set with respect to the first line 71. The third line 73 extends in a direction intersecting with (e.g., substantially perpendicular to) the first line 71 and extends along a third side 5c of the semiconductor chip 5. As a result, an L-shaped first reinforcing portion is formed. The fourth line 74 extends in a direction intersecting with (e.g., substantially perpendicular to) the second line 72 and extends along a fourth side 5d of the semiconductor chip 5. As a result, an L-shaped second reinforcing portion is formed.

As shown in FIG. 12, gap g3 is provided between the first line 71 and the second line 72. Therefore, resin injected via the injection port 61 can flow to the back portion 62 via gap g3 between the first line 71 and the second line 72.

As shown in FIG. 12, the reinforcing portion 24 has a portion extending toward the back portion 62. In this embodiment, the first line 71 and the second line 72 extend toward the back portion 62. As a result, a portion of resin injected via the injection port 61 is guided by means of grooves 24a and protrusions 24b of the first line 71 and second line 72 and led toward the back portion 62.

With the above configuration, like the first embodiment, the semiconductor chip 5 can be prevented from being damaged. Further, according to the configuration of this embodiment, like the fourth embodiment, the filling property of the sealing portion 6 can be enhanced.

### Sixth Embodiment

Next, a semiconductor device 1 according to a sixth embodiment is explained with reference to FIG. 13. FIG. 13 is a plan view schematically showing a holder 4 of the semiconductor device 1. The configurations that have the same or similar functions as or to those of the configurations of the fourth embodiment are denoted by the same symbols and the explanation thereof is omitted. Further, the configurations other than those explained below are the same as those of the fourth embodiment.

As shown in FIG. 13, in this embodiment, a reinforcing portion 24 projects from a second surface 4b of the holder 4. The reinforcing portion 24 has a first line 64, a second line 65, a third line 66, a fourth line 67 and a fifth line 81. The configurations of the first to fourth lines 64, 65, 66, 67 are substantially the same as those of the fourth embodiment.

The fifth line 81 is positioned on the back of a semiconductor chip 5 and is positioned on the back of the central portion of the semiconductor chip 5. The fifth line 81 extends toward a back portion 62. As a result, a portion of resin injected via an injection port 61 is guided by means of the fifth line 81 and led toward the back portion 62.

With the above configuration, like the first embodiment, the semiconductor chip 5 can be prevented from being damaged. Further, according to the configuration of this embodiment, like the fourth embodiment, the filling property of the sealing portion 6 can be enhanced.

### Seventh Embodiment

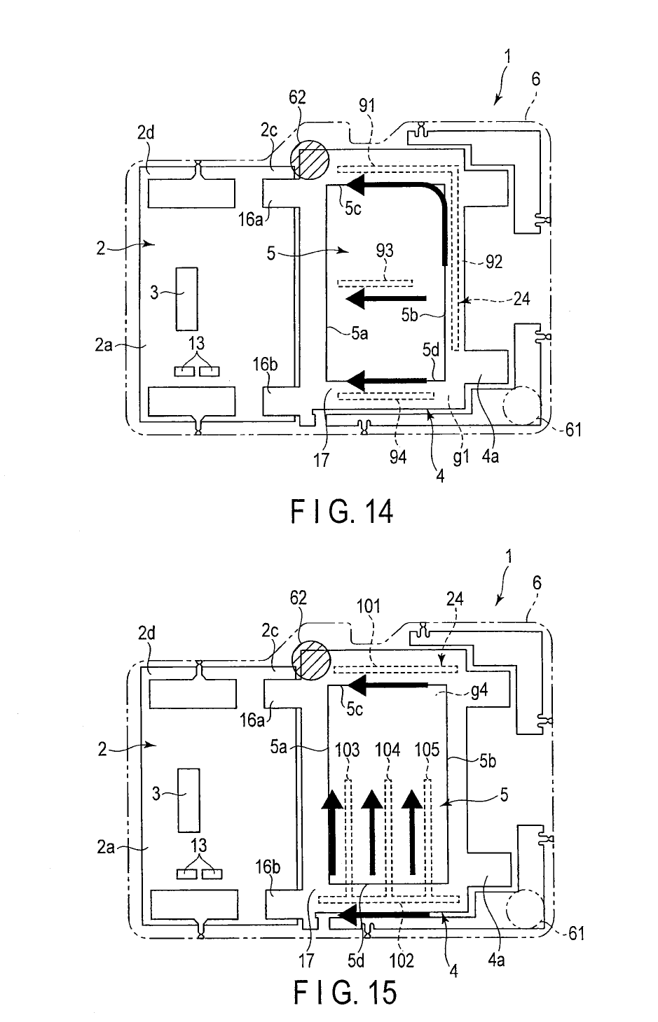

Next, a semiconductor device 1 according to a seventh embodiment is explained with reference to FIG. 14. FIG. 14 is a plan view schematically showing a holder 4 of the semiconductor device 1. The configurations that have the same or similar functions as or to those of the configurations of the fourth embodiment are denoted by the same symbols and the explanation thereof is omitted. Further, the configurations other than those explained below are the same as those of the fourth embodiment.

As shown in FIG. 14, in this embodiment, a reinforcing portion 24 projects from a second surface 4b of the holder 4. The reinforcing portion 24 has a first line 91, a second line 92, a third line 93 and a fourth line 94.

The first line 91 extends along a third side 5c of a semiconductor chip 5. The first line 91 extends toward a back portion 62. The second line 92 extends in a direction intersecting with (e.g., substantially perpendicular to) the first line 91 and extends along a second side 5b of the semiconductor chip 5. Therefore, an L-shaped reinforcing portion 24 is formed. The third line 93 is positioned on the back of the central portion of the semiconductor chip 5. The third line 93 extends substantially parallel to the first line 91. The fourth line 94 extends along a fourth side 5d of the semiconductor chip 5.

With the above configuration, like the first embodiment, the semiconductor chip 5 can be prevented from being damaged. Further, with the configuration of this embodiment, like the fourth embodiment, the filling property of a sealing portion 6 can be enhanced.

### Eighth Embodiment

Next, a semiconductor device 1 according to an eighth embodiment is explained with reference to FIG. 15. FIG. 15 is a plan view schematically showing a holder 4 of the semiconductor device 1. The configurations that have the same or similar functions as or to those of the configurations of the fourth embodiment are denoted by the same symbols and the explanation thereof is omitted. Further, the configurations other than those explained below are the same as those of the fourth embodiment.

As shown in FIG. 15, in this embodiment, a reinforcing portion 24 projects from a second surface 4b of the holder 4. The reinforcing portion 24 has a first line 101, a second line 102, a third line 103, a fourth line 104 and a fifth line 105.

The first line 101 extends along a third side 5c of a semiconductor chip 5. The first line 101 extends toward a back portion 62. The second line 102 extends along a fourth side 5d of the semiconductor chip 5. The third to fifth lines 103, 104, 105 extend in a direction intersecting with (e.g., substantially perpendicular to) the second line 102 and extend toward the first line 101. Gap g4 is provided between the first line 101 and the third to fifth lines 103, 104, 105.

With the above configuration, like the first embodiment, the semiconductor chip 5 can be prevented from being damaged. Further, with the configuration of this embodiment, like the fourth embodiment, the filling property of a sealing portion 6 can be enhanced.

As described above, the first to eighth embodiments have been explained, but this invention is not limited to the above embodiments. The configurations related to the above embodiments can be realized by adequately modifying, exchanging or combining the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a board;
a controller chip on the board;
a holder formed of a metal plate thinner than the board, the holder comprising a first portion attached to the board and a second portion extending in an exterior of the board;
a semiconductor chip on the second portion of the holder; and
a reinforcing portion formed by bending a portion of the second portion of the holder, the reinforcing portion comprising a groove depressed from a surface of the holder and a linear protrusion on a back of the groove.

2. The device of claim 1, wherein
the holder comprises a first surface and a second surface opposite to the first surface, the first surface comprising the semiconductor chip, and
the reinforcing portion is in a position covered by the semiconductor chip, and the protrusion is on the second surface.

3. The device of claim 2, wherein
the reinforcing portion is in a frame form to surround a central portion of the semiconductor chip.

4. The device of claim 2, wherein
the reinforcing portion comprises a portion located on a back of a central portion of the semiconductor chip.

5. The device of claim 1, wherein
the holder comprises a first surface and a second surface opposite to the first surface, the first surface comprising the semiconductor chip, and
the reinforcing portion is in a position separated from the semiconductor chip, and the protrusion is on the first surface.

6. The device of claim 5, wherein
the reinforcing portion surrounds at least a part of the semiconductor chip.

7. The device of claim 1, further comprising:
a bonding wire between the semiconductor chip and board, and
a sealing portion integrally sealing the controller chip, the holder, the semiconductor chip, the reinforcing portion and the bonding wire.

8. The device of claim 7, wherein
the sealing portion comprises an injection port of mold resin used for forming the sealing portion, and a region, the semiconductor chip located between the region and the injection port, and
the reinforcing portion comprises a portion extending toward the region of the sealing portion.

9. A semiconductor device comprising:
a metal holder;
a semiconductor chip on the holder; and
a reinforcing portion formed by bending a portion of the holder, the reinforcing portion comprising a groove depressed from a surface of the holder and a protrusion on a back of the groove.

10. A method of manufacturing a semiconductor device comprising:
preparing a base member,
forming an external form of a holder and a reinforcing portion substantially simultaneously by pressing the base member, the reinforcing portion comprising a groove depressed from a surface of the holder and a protrusion on a back of the groove,
mounting a semiconductor chip on the holder, and
sealing the holder and the semiconductor chip by mold resin.

11. The method of claim 10, wherein
the holder comprises a first surface and a second surface opposite to the first surface,
the protrusion is on the second surface, and
the semiconductor chip is on the first surface and overlaps with the reinforcing portion.

12. The method of claim 11, wherein
the reinforcing portion is in a frame form to surround a central portion of the semiconductor chip.

13. The method of claim 11, wherein
the reinforcing portion comprises a portion located on a back of a central portion of the semiconductor chip.

14. The method of claim 10, wherein
a sealing portion formed of the mold resin comprises an injection port of the mold resin and a region, the semiconductor chip located between the region and the injection port,
the reinforcing portion comprises a portion extending toward the region of the sealing portion, and
a portion of the mold resin flows along the reinforcing portion to fill the region of the sealing portion.
